(19) United States
(12) Patent Application Publication
(10) Pub. No.: US 2015/0263731 A1
(43) Pub. Date: Sep. 17, 2015

(54) LEVEL SHIFT CIRCUIT

(71) Applicant: Kabushiki Kaisha Toshiba, Tokyo (JP)

(72) Inventor: Natsuki Kushiyama, Kawasaki Kanagawa (JP)

(21) Appl. No.: 14/642,442

(22) Filed: Mar. 9, 2015

(30) Foreign Application Priority Data
Mar. 14, 2014 (JP) 2014-052286

(51) Int. Cl. H03K 19/0185; H03K 19/017

(52) U.S. Cl. CPC H03K 19/0185; H03K 19/017

(57) ABSTRACT

A level shift circuit of an embodiment includes: an input circuit configured to receive an input signal and connected to first and second power supply lines; first and second signal paths connected in parallel between the first power supply line and a third power supply line; first and second switching elements configured to control conduction of the first and second signal paths, respectively, based on the input signal; first and second diodes and a cross-coupled circuit arranged towards the third power supply line on the first and second signal paths; and an output circuit connected to the third power supply line and a fourth power supply line, and configured to output an output signal based on at least one of a signal appearing at a first node at one end of the first diode and a signal appearing at a second node at one end of the second diode.

### CROSS REFERENCE TO RELATED APPLICATION

This application is based upon and claims the benefit of priority from the prior Japanese Patent Applications No. 2014-052286, filed on Mar. 14, 2014; the entire contents of which are incorporated herein by reference.

### FIELD

Embodiments described herein relate generally to a level shift circuit.

### BACKGROUND

Conventionally, a level shift circuit is employed when transmitting signals to an electric circuit using different power supply voltages. Some level shift circuits of this kind have a tolerant function in consideration of the withstand voltages of elements used in the circuit. The tolerant function is a function that ensures that a voltage that exceeds a withstand voltage is not applied to the respective elements in the circuit, and a tolerant structure is adopted in the circuit to realize the tolerant function.

However, a comparatively long time period is required for a state transition of the aforementioned kind of barrier MOS transistor, and consequently operations for driving the barrier MOS transistor are slow. Therefore, in a case where the level shift circuit is operated at high speed at a comparatively high frequency, in some cases an output waveform of the level shift circuit is distorted due to a delay in signal transmission in the tolerant structure portion.

### BRIEF DESCRIPTION OF THE DRAWINGS

FIG. 1 is a circuit diagram illustrating a level shift circuit according to a first embodiment of the present invention;

FIG. 2 is a circuit diagram illustrating an example of an off-chip driver with a tolerant structure;

FIG. 3 is a circuit diagram illustrating related art of the level shift circuit of embodiments of the present invention, that is a level shift circuit that can be adopted as a level shift circuit illustrated in FIG. 2;

FIG. 4 is a circuit diagram illustrating a second embodiment of the present invention;

FIG. 5 is a circuit diagram illustrating a third embodiment of the present invention;

FIG. 6 is a circuit diagram illustrating a fourth embodiment of the present invention;

FIG. 7 is a circuit diagram illustrating the fourth embodiment of the present invention;

FIG. 8 is a timing chart illustrating outputs of respective inverters shown in FIG. 7; and

FIG. 9 is a circuit diagram illustrating a fifth embodiment of the present invention.

### DETAILED DESCRIPTION

A level shift circuit of an embodiment described herein includes: a first power supply line to which a first voltage is supplied; a second power supply line to which a second voltage that is higher than the first voltage is supplied; a third power supply line to which a third voltage that is higher than the second voltage is supplied; a fourth power supply line to which a fourth voltage that is higher than the first voltage and lower than the third voltage is supplied; an input circuit to which voltages are supplied from the first and second power supply lines, and which is configured to receive an input signal; first and second signal paths that are connected in parallel between the first power supply line and the third power supply line; first and second switching elements configured to control conduction of the first and second signal paths, respectively, based on the input signal that the input circuit receives; first and second diodes provided on the first and second signal paths, respectively, at positions that are on a side of the third power supply line with respect to the first and second switching elements; a cross-coupled circuit configured to make one of a first node which is located on the first path at a position that is on the side of the third power supply line with respect to the first diode and a second node which is located on the second path at a position that is on the side of the third power supply line with respect to the second diode a high level and make the other of the first node and the second node a low level, and that is provided on the first and second signal paths at a position that is on the side of the third power supply line with respect to the first and second nodes; and an output circuit to which voltages are supplied from the third and fourth power supply lines, and which is configured to output an output signal based on at least one of a signal appearing at the first node and a signal appearing at the second node.

Embodiments of the present invention are described in detail hereunder with reference to the drawings.

### First Embodiment

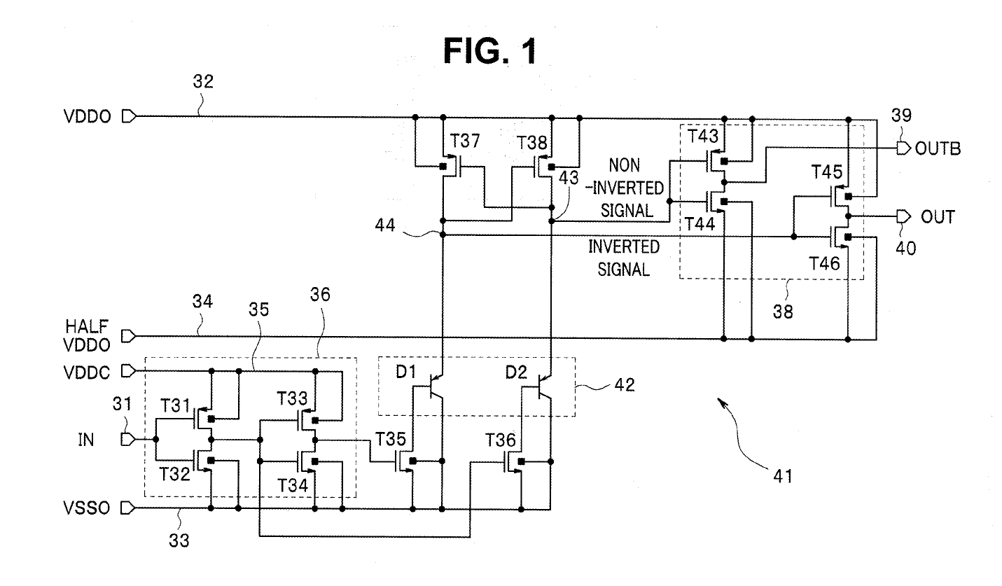

FIG. 1 is a circuit diagram illustrating a level shift circuit according to a first embodiment of the present invention.

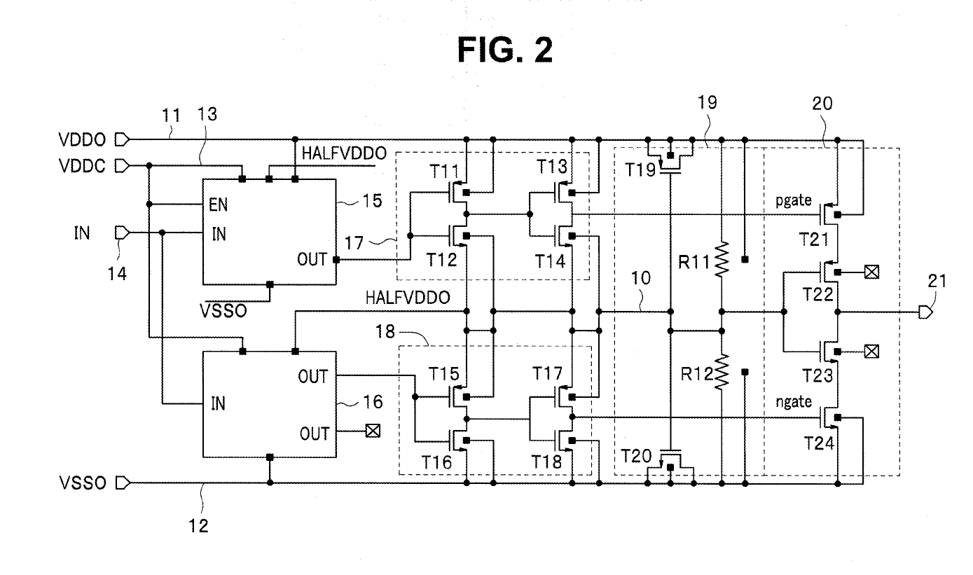

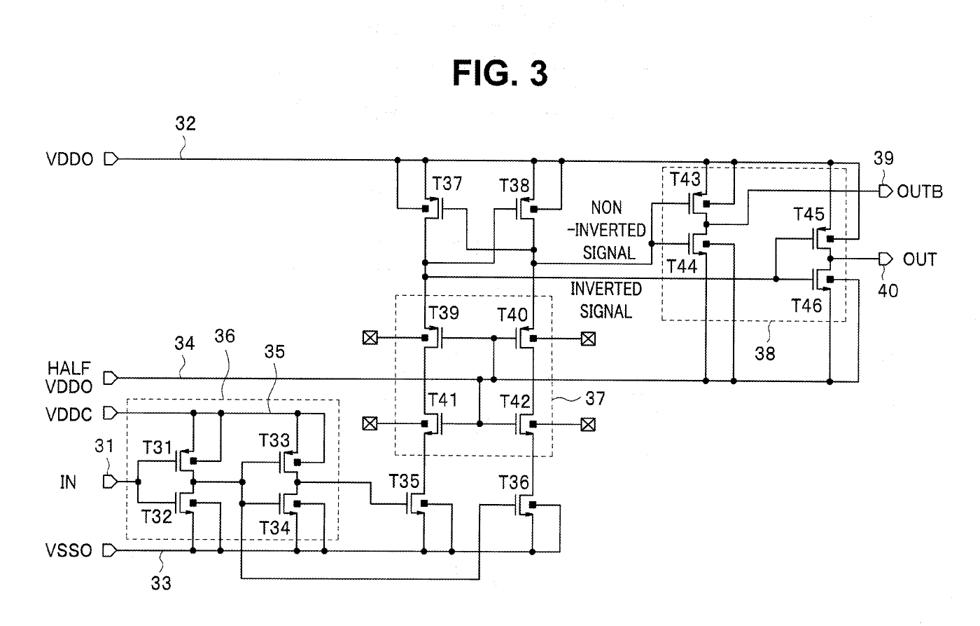

First, referring to FIG. 2 and FIG. 3, a problem that arises due to an operating delay caused by a tolerant structure will be described. FIG. 2 is circuit diagram illustrating an example of an off-chip driver with a tolerant structure. FIG. 3 is a circuit diagram illustrating related art of the level shift circuit of the present embodiment, that is a level shift circuit that can be adopted as a level shift circuit illustrated in FIG. 2.

Transistors that have a plurality of gate oxide film thicknesses are used in a semiconductor integrated circuit device. The transistors have withstand voltages that are in accordance with the relevant gate oxide film thickness. In general, only transistors of fixed kinds can be used in a single semiconductor integrated circuit device, for example, two kinds of transistors that have different gate oxide film thicknesses. Multiple kinds of circuits for which the power supply voltages are different to each other are constructed inside a semiconductor integrated circuit device. For example, in some cases it is necessary to use a transistor having a withstand voltage of 1.98 V (hereunder, referred to as “medium film transistor”) in a circuit in which a power supply voltage up to 3.3 V is allowed. In this case, a circuit design (tolerant design) is required that ensures that a voltage of 1.98 V or more is not applied between respective terminals of the medium film transistor.

In FIG. 2, the output of a logic circuit of the previous stage is inputted as an input signal IN to an input terminal 14. The input signal IN is a signal that changes from a voltage VSSO (for example, 0 V) to a voltage VDDC (for example, 1.1 V). A power supply voltage VDDO (for example, 2.5 to 3.3 V) is supplied to a power supply line 11. A power supply voltage VSSO (for example, 0 V) is supplied to a power supply line 12. The power supply voltage VDDC is supplied to a power supply line 13.

An intermediate power supply voltage generation portion 19 has resistances R11 and R12 that are connected in series between the power supply line 11 and the power supply line 12. Transistors T19 and T20 act as capacitances, and the intermediate power supply voltage generation portion 19 generates a power supply voltage HALFVDDO (for example, 1.25 to 1.65 V) that is ½ of VDDO by resistance voltage division by the resistances R11 and R12. The power supply voltage HALFVDDO is supplied to a power supply line 10.

Resistances R11 and R12 are made of poly-silicon. There is a dielectric film underneath the resistance R11 and there is an N-well underneath the dielectric film. There is a dielectric film underneath the resistance R12 and there is a P-well underneath the dielectric film. Note that, in FIG. 2, a connecting line is drawn from the vicinity of the center of the symbol of the resistance R11 to the power supply line 11. This means that the potential at the N-well which resides underneath the R11 is fixed to VDDO. Similarly, a connecting line extending from the vicinity of the center of the symbol of the resistance R12 to the power supply line 12 means that the potential at the P-well underneath the R12 is fixed to VASSO. The potentials of the wells are thus fixed to predetermined potentials, thereby capable of suppressing the potential variation caused due to the stray capacity between the poly-silicon used for the resistances and the wells, during the operation. In also other drawings, the resistances are drawn in the similar way.

The off-chip driver in FIG. 2 is configured so as to convert the input signal IN to a signal with an amplitude of VDDO (for example, 2.5 to 3.3 V) from VSSO (0 V), and output the resulting signal. In this case, a tolerant function is achieved by handling a signal with a level from HALFVDDO to VDDO using a circuit portion arranged between the power supply line 10 and the power supply line 11 in FIG. 2, and handling a signal with a level from VSSO to HALFVDDO using a circuit portion arranged between the power supply line 10 and the power supply line 12.

The input signal IN is supplied to level shift circuits 15 and 16. The level shift circuit 16 outputs signal with a level between VSSO and HALFVDDO in accordance with the input signal IN. Likewise, the level shift circuit 15 outputs signal with a level between HALFVDDO and VDDO in accordance with the input signal IN.

The output of the level shift circuit 16 is inputted to a buffer circuit 18 constituted by a two-stage inverter. The buffer circuit 18 subjects the output of the level shift circuit 16 to waveform shaping, and supplies the resulting output as ngate to a gate of a transistor T24 of an output circuit 20. Voltages applied to the respective terminals of four transistors T15 to T18 of the buffer circuit 18 are within a range from VSSO to HALFVDDO, and the transistors can be constituted by a medium film transistor having a withstand voltage of 1.98 V.

The output of the level shift circuit 15 is inputted to a buffer circuit 17 constituted by a two-stage inverter. The buffer circuit 17 subjects the output of the level shift circuit 15 to waveform shaping, and supplies the resulting output as pgate to a gate of a transistor T21 of the output circuit 20. Voltages applied to the respective terminals of four transistors T11 to T14 of the buffer circuit 17 are within the range from HALFVDDO to VDDO, and the transistors can be constituted by a medium film transistor having a withstand voltage of 1.98 V.

The output circuit 20 has a stacked structure, and includes transistors T23 and T24 that handle outputs with a level between VSSO and HALFVDDO and transistors T21 and T22 that handle outputs with a level between HALFVDDO and VDDO among the outputs that change from VSSO to VDDO. The power supply voltage HALFVDDO is continuously applied to the gates of the transistors T22 and T23. Further, the level of pgate that is supplied to the gate of the transistor T21 is between HALFVDDO and VDDO, and the level of ngate that is supplied to the gate of the transistor T24 is between VSSO and HALFVDDO. Accordingly, with respect to the transistors T21 to T24 also, a voltage exceeding HALFVDDO is not applied between the respective terminals, and the transistors can be constituted by a medium film transistor.

Note that, back gates of the transistors T22 and T23 are in a floating state. In the following drawings, a fact that the back gates are in a floating state is indicated using a symbol in which an x mark is placed inside a square in the relevant drawing.

In this connection, a particular problem does not exist with respect to the level shift circuit 16 since the level shift circuit 16 only handles voltages of a level between VSSO and HALFVDDO. In contrast, the level shift circuit 15 shifts an input having a level between VSSO (0 V) and VDDC (1.1 V) to an output having a level between HALFVDDO (1.25 to 1.65 V) and VDDO (2.5 to 3.3 V) and outputs the output. That is, a tolerant design is required for the level shift circuit 15 because the level shift circuit 15 handles levels from VSSO to VDDO.

FIG. 3 illustrates an example in which the related art is used as the level shift circuit 15.

The input signal IN in FIG. 2 is inputted to an input terminal 31 in FIG. 3. The voltage VDDO is supplied to a power supply line 32, the voltage VSSO is supplied to a power supply line 33, and the voltage HALFVDDO is supplied to a power supply line 34. Further, the voltage VDDC is supplied to a power supply line 35.

The input signal IN is inputted to an input circuit 36. The input circuit 36 is constituted by an inverter formed by transistors T31 and T32 and an inverter formed by transistors T33 and T34 that are connected between the power supply line 35 and the power supply line 33. The inverter formed by the transistors T31 and T32 inverts the input signal IN and applies the resulting signal to the gates of transistors T33, T34 and T36. The inverter formed by the transistors T33 and T34 inverts the inverted signal of the input signal IN again, and applies the resulting signal to the gate of a transistor T35.

Since the power supply voltages VDDC and VSSO are supplied to the input circuit 36, and the input circuit 36 thus handles signals with levels in the range of VSSO to VDDC, the respective transistors T31 to T34 of the input circuit 36 can be constituted by a medium film transistor. The input signal IN having a level within the range of VSSO to VDDC that is received by the input circuit 36 is converted to an output signal OUT having a level within the range of HALFVDDO to VDDO by an output circuit 38 constituted by transistors T43 to T46.

The output circuit 38 is constituted by an inverter formed by the transistors T43 and T44 and an inverter formed by the transistors T45 and T46 that are connected between the power supply line 32 and the power supply line 34. A non-inverted signal that is based on the input signal IN is applied to the inverter formed by the transistors T43 and T44, and the inverter outputs an inverted output OUTB to an output terminal 39. An inverted signal that is based on the input signal IN is applied to the inverter formed by the transistors T45 and T46, and the inverter outputs a non-inverted output OUT to an output terminal 40.

The power supply voltages VDDO and HALFVDDO are supplied to the output circuit 38, and the output circuit 38 outputs an output having a level within the range of HALFVDDO to VDDO. Accordingly, the respective transistors T43 to T46 of the output circuit 38 can be constituted by a medium film transistor.

The transistors T35 to T42 in FIG. 3 are a circuit portion that transmits the input signal IN received at the input circuit 36 to the output circuit 38 as a non-inverted signal or an inverted signal. A cross-coupled circuit constituted by transistors T37 and T38, a barrier circuit 37 constituted by transistors T39 to T42, and the transistors T35 and T36 are connected between the power supply line 32 and the power supply line 33.

The transistors T35 and T36 turn “on” or “off” in accordance with the input signal IN. When the input signal IN is “high” level (hereunder, referred to as “H level”), the transistor T35 turns “on” and the transistor T36 turns “off”. When the transistor T35 turns “on”, the gate of a coupling transistor T38 becomes “low” level (hereunder, referred to as “L level”), the transistor T38 turns “on”, and the drain thereof becomes H level. Further, since the transistor T37 turns “off” and the transistor T36 is “off”, the H level of the drain of the coupling transistor T38 and the L level of the drain of the transistor T37 are maintained. A non-inverted signal of the same polarity as the input signal IN appears at the transistor T38, and the non-inverted signal is supplied to the gates of the transistors T43 and T44 of the output circuit 38. Similarly, an inverted signal of reverse polarity to the input signal IN appears at the drain of the transistor T37, and the inverted signal is applied to the gates of the transistors T45 and T46 of the output circuit 38.

The power supply voltage HALFVDDO is applied to the gates of the respective transistors T39 to T42 of the barrier circuit 37. Accordingly, application of VSSO to the drains of the coupling transistors T37 and T38 is prevented by the transistors T39 and T40 of the barrier circuit 37, and these drains can be limited to a level in the vicinity of HALFVDDO. Further, application of VDDO to the drains of the transistors T35 and T36 is prevented by the transistors T41 and T42 of the barrier circuit 37, and these drains can be limited to a level in the vicinity of HALFVDDO.

Accordingly, a voltage equal to or greater than HALFVDDO is not applied to any of the respective transistors T39 to T42 of the barrier circuit 37, the coupling transistors T37 and T38, and the transistors T35 and T36. Thus, all of the transistors T35 to T42 can be constituted by a medium film transistor.

Therefore, while maintaining a tolerant function, the level shift circuit shown in FIG. 3 can shift the level of the input signal IN having a level in the range of VSSO to VDDC to the output signal OUT (OUTB) having a level in the range of HALFVDDO to VDDO, and output the output signal OUT (OUTB).

However, in order to change the polarities of the non-inverted signal and the inverted signal that appear at the drains of the coupling transistors T37 and T38 in accordance with the input signal IN, it is necessary to drive the transistors T39 to T42 which are at two stages that constitute the barrier circuit 37, and thus a comparatively long period of time is required for state transition of the non-inverted signal and inverted signal. Consequently, in the circuit illustrated in FIG. 3, depending on conditions such as the performance of the transistors, the power supply voltages, and the temperature, in some cases the speed of a level change in an output waveform is slow and the output waveform is distorted.

Therefore, according to the present embodiment, by constructing a high-speed barrier circuit, it is possible to have a tolerant function and also reliably obtain an output waveform that is not distorted. The present embodiment will now be described taking as an example a level shift circuit that shifts the level of an input signal IN for which the level range changes within a range from VSSO (for example, 0 V) to VDDC (for example, 1.1 V) to an output signal OUT for which the level range changes within a range from HALFVDDO (for example, 1.25 to 1.65 V) to VDDO (for example, 2.5 to 3.3 V). Note that, FIG. 1 illustrates an example in which, in particular, HALFVDDO is 1.25 V and VDDO is 2.5 V.

In a level shift circuit 41 shown in FIG. 1, an input signal IN is inputted to an input circuit 36 through an input terminal 31. A power supply voltage VDDC is supplied to a power supply line 35, and a power supply voltage VSSO is supplied to a power supply line 33. A source-drain path of a PMOS transistor T31 and a drain-source path of an NMOS transistor T32 are serially connected between the power supply line 35 and the power supply line 33. The input signal IN from the input terminal 31 is applied to the gates of the transistors T31 and T32. The transistors T31 and T32 function as an inverter, and invert the input signal IN and output the inverted signal.

Further, a source-drain path of a PMOS transistor T33 and a drain-source path of an NMOS transistor T34 are serially connected between the power supply line 35 and the power supply line 33. The output of the inverter formed by the transistors T31 and T32 of the previous stage is applied to the gates of the transistors T33 and T34. The transistors T33 and 134 function as inverters, and output an inverted signal of the inputted signal.

The input circuit 36 is constituted by the aforementioned transistors T31 to T34, and applies an inverted signal of the input signal IN to the gate of an NMOS transistor T36 that is a switching element, and also inverts the inverted signal of the input signal IN again and applies the resulting signal to the gate of an NMOS transistor T35 that is a switching element.

A non-inverted signal appearing at a non-inverting node 43 and an inverted signal appearing at an inverting node 44 that are described later are applied to the output circuit 38. The voltage VDDO is supplied to the power supply line 32, and the voltage HALFVDDO is supplied to the power supply line 34. A source-drain path of a PMOS transistor T43 and a drain-source path of an NMOS transistor T44 are serially connected between the power supply line 32 and the power supply line 34. The non-inverted signal from the non-inverting node 43 is applied to the gates of the transistors T43 and T44. The transistors T43 and T44 function as an inverter, and output an inverted signal of the inputted non-inverted signal as an inverted output OUTB to an output terminal 39.

A source-drain path of a PMOS transistor T45 and a drain-source path of an NMOS transistor T46 are connected in series between the power supply line 32 and the power supply line 34. An inverted signal from the inverting node 44 is applied to the gates of the transistors T45 and T46. The transistors T45 and T46 function as an inverter, and output an inverted signal of the inputted inverted signal as a non-inverted output OUT to an output terminal 40.

A source-drain path of a PMOS coupling transistor T37 is connected between the power supply line 32 and the inverting node 44. A source-drain path of a PMOS coupling transistor T38 is connected between the power supply line 32 and the non-inverting node 43. The gate of the transistor T37 is connected to the drain (non-inverting node 43) of the transistor T38, and the gate of the transistor T38 is connected to the drain (inverting node 44) of the transistor 137, and thus a cross-coupled circuit is constituted by the transistors T37 and T38.

In the present embodiment, the inverting node 44 is connected to the emitter of a PNP-type bipolar transistor D1, and the base of the transistor D1 is connected to the power supply line 33 through the drain-source path of the transistor T35. Further, the non-inverting node 43 is connected to the emitter of a PNP-type bipolar transistor D2, and the base of the transistor D2 is connected to the power supply line 33 through the drain-source path of the transistor T36. That is, since the transistors D1 and D2 are used as P-N junction diodes, hereinafter, the transistors D1 and D2 may also be referred to as diodes D1 and D2. Note that the collectors of the transistors D1 and D2 are connected to the power supply line 33.

Thus, in the present embodiment, a barrier circuit 42 constituted by the diodes D1 and D2 is adopted. Although the barrier circuit 37 shown in FIG. 3 that is a circuit of the related art must necessarily be constituted by MOS transistors at two stages, the barrier circuit 42 of the present embodiment can be constituted by the single-stage diodes D1 and D2.

Note that, although an example in which a diode is constituted by a bipolar transistor is shown in FIG. 1, another kind of diode may be adopted as long as the non-inverting node 43 and the drain of the transistor T36 are diode-connected, and the inverting node 44 and the drain of the transistor T35 are diode-connected.

Note that the back gates of the respective PMOS transistors T31 and T33 are connected to the power supply line 35, the back gates of the respective PMOS transistors T37, T38, T43 and T45 are connected to the power supply line 32, the back gates of the respective NMOS transistors T32 and T34 to T36 are connected to the power supply line 33, and the back gates of the respective NMOS transistors T44 and T46 are connected to the power supply line 34. Note that the connecting locations of the back gates that are shown in FIG. 1 are the connecting locations in an ideal case, and the connecting locations are not limited to the example illustrated in FIG. 1.

Next, operations in the embodiment configured as described above will be described.

In this case, it is assumed that the input signal IN for which the L level is VSSO and the H level is VDDC is inputted to the input terminal 31. The input signal IN is inverted by the inverter formed by the transistors T31 and T32 of the input circuit 36, and the inverted signal is supplied to the gate of the transistor T36. The inverter formed by the transistors T33 and T34 of the input circuit 36 inverts the inverted signal again and supplies the resulting non-inverted signal to the gate of the transistor T35.

For example, when the input signal IN is at H level, the transistor T35 turns “on” and the transistor T36 turns “off”. When the transistor T35 turns “on”, a change in the drain potential of the transistor T35 is transmitted to the inverting node 44 at high speed by the diode D1, the level of the inverting node 44 transitions to L level, and the transistor T38 of the cross-coupled circuit turns “on”. As a result, the level of the non-inverting node 43 transitions to H level. Since the non-inverting node 43 is at H level, the transistor T37 remains “off” and the inverting node 44 maintains L level.

The inverted signal of the inverting node 44 is supplied to the gates of the transistors T45 and T46 of the output circuit 38. The inverter formed by the transistors T45 and T46 inverts the inverted signal, and outputs the non-inverted output OUT to the output terminal 40. On the other hand, the non-inverted signal of the non-inverting node 43 is supplied to the gates of the transistors T43 and T44 of the output circuit 38. The inverter formed by the transistors T43 and T44 inverts the non-inverted signal, and outputs the inverted output OUTB to the output terminal 39.

When the inverting node 44 is at L level, the non-inverted output OUT at H level is outputted from the output terminal 40. The non-inverted output OUT in this case is set to the level of VDDO by the transistor T45. Further, when the non-inverting node 43 is at H level, the inverted output OUTB at L level is outputted from the output terminal 39. The inverted output OUTB in this case is set to the level of HALFVDDO by the transistor T44.

Conversely, when the input signal IN is at L level, the transistor T35 turns “off” and the transistor T36 turns “on”. When the transistor T36 turns “on”, a change in the drain potential of the transistor T36 is transmitted to the non-inverting node 43 at high speed by the diode D2, the level of the non-inverting node 43 transitions to L level, and the transistor T37 of the cross-coupled circuit turns “on”. As a result, the level of the inverting node 44 transitions to H level. Since the inverting node 44 is at H level, the transistor T38 remains “off”, and the non-inverting node 43 maintains L level.

When the non-inverting node 43 is at L level, the inverted output OUTB at H level is outputted from the output terminal 39. The inverted output OUTB in this case is set to the level of VDDO by the transistor T43. When the inverting node 44 is at H level, the non-inverted output OUT at L level is outputted from the output terminal 40. The non-inverted output OUT in this case is set to the level of HALFVDDO by the transistor T46.

Thus, in accordance with whether the input signal IN is at L level or H level, an output at L level or H level that changes within the range from HALFVDDO to VDDO is obtained.

A change in the drain potential of the transistor T35 or T36 is transmitted at extremely high speed to the inverting node 44 or non-inverting node 43 by the diode D1 or D2, respectively. Accordingly, a change in the input signal IN appears as a change in the non-inverted signal and the inverted signal in a sufficiently short time period, and is transmitted to the output circuit 38. Thus, a change in the input signal IN reliably appears as a change in the output waveform, and the output waveform is not distorted.

### (Tolerant Design)

The voltage VSSO or VDDC is supplied through the power supply lines 35 and 33 to the transistors T31 to T34 constituting the input circuit 36, and it is sufficient if the transistors T31 to T34 have a withstand voltage greater than or equal to VDDC. Further, the voltage VDDO or HALFVDDO is supplied through the power supply lines 32 and 34 to the transistors T43 to T46 constituting the output circuit 38, and it is sufficient if the transistors 143 to 146 have a withstand voltage greater than or equal to HALFVDDO. Accordingly, with respect to the transistors T31 to T34 and T43 to T46, a transistor having a withstand voltage greater than or equal to HALFVDDO can be utilized for these transistors, for example, a medium film transistor having a withstand voltage of 1.98 V.

On the other hand, with respect to the transistors T35 to T38, it is necessary to adopt a tolerant structure in a case where the transistors T35 to T38 are connected between the power supply line 32 and the power supply line 33 and a medium film transistor is utilized for these transistors. In the present embodiment, a tolerant structure is obtained by means of the barrier circuit 42.

A forward voltage is, for example, approximately 0.7 to 1 V at the diodes D1 and D2 constituting the barrier circuit 42. Accordingly, in a case where VDDO is 2.5 V, the drains of the transistors T35 and T36 are restricted to 1.5 to 1.8 V. Further, the drains of the coupling transistor T37 and T38 are restricted to 0.7 to 1 V. Accordingly, with respect to the transistors T35 to T38, a maximum voltage applied to the respective terminals including the back gates is between 1.5 and 1.8 V. Therefore, the transistors T35 to T38 can also be constituted by medium film transistors.

Note that, although in FIG. 1 an example is illustrated in which the single-stage diodes D1 and D2 are connected between the non-inverting node 43 and the drain of the transistor T36 and between the inverting node 44 and the drain of the transistor T35, a configuration can also be adopted in which two or more stages of diodes are respectively connected between the non-inverting node 43 and the drain of the transistor T36 and between the inverting node 44 and the drain of the transistor T35. Since the forward voltage of the diode is between 0.7 and 1 V per stage, in a case where two stages of diodes are connected, for example, a voltage drop of between 1.4 and 2V can be obtained. Accordingly, in this case, even if VDDO is 3.3 V and HALFVDDO is 1.65 V, a tolerant function is obtained. Even in a case where diodes are provided at two stages, it is possible to transmit a change in the drain potential of the transistors T35 and T36 at a sufficiently high speed to the inverting node 44 and non-inverting node 43.

For example, in a case where VDDO is between 2.5 and 2.7 V, a tolerant function can be obtained by constructing a barrier circuit using diodes at a single stage, while in a case where VDDO is between 3.0 and 3.3V, a tolerant function can be obtained by constructing a barrier circuit using diodes at two stages.

Thus, in the present embodiment, a barrier circuit is constructed using diodes with a sufficiently fast speed, and a change in the input signal can be transmitted to the output circuit at high speed while maintaining a tolerant function. Furthermore, it is possible to prevent a distortion in an output waveform and reliably perform level shifting irrespective of conditions such as the performance of transistors, the power supply voltages and the temperature.

### Second Embodiment

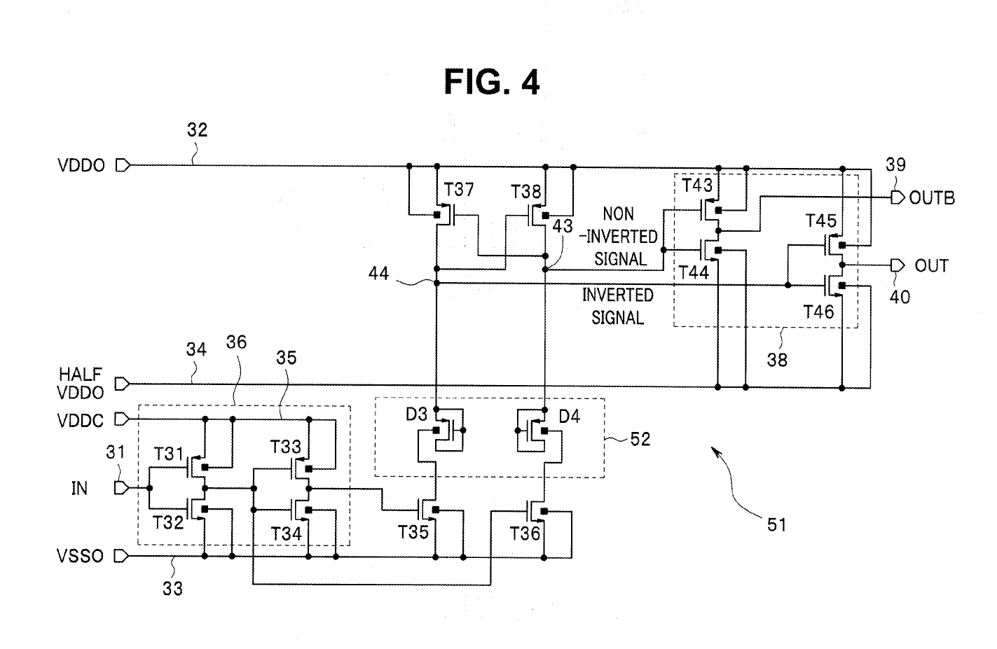

FIG. 4 is a circuit diagram illustrating a second embodiment of the present invention. Components in FIG. 4 that are the same as in FIG. 1 are denoted by the same reference numbers and a description of such components is omitted hereunder.

A level shift circuit 51 of the present embodiment differs from the first embodiment in that a barrier circuit 52 employing diodes formed by transistors D3 and D4 is used instead of the barrier circuit 42 employing the diodes D1 and D2 of the first embodiment.

The source, gate and drain of a PMOS transistor D3 are commonly connected, and the transistor D3 is connected to the inverting node 44. The back gate of the transistor D3 is connected to the drain of the transistor T35. Further, the source, gate and drain of a PMOS transistor D4 are commonly connected, and the transistor D4 is connected to non-inverting node 43. The back gate of the transistor D4 is connected to the drain of the transistor T36. These transistors T35 and T36 are used as diodes using a P-N junction between a P-diffusion layer constituting the source and drain and an N-well constituting the back gate. Since the transistors D3 and D4 are used as P-N junction diodes, hereinafter the transistors D3 and D4 may also be referred to as diodes D3 and D4.

Note that, although FIG. 4 illustrates an example in which diodes are constituted by PMOS transistors, if a triple-well structure is adopted in which a P-type buried layer is provided on an N-type substrate, and an N-type well is further formed on the buried layer, it is also possible to use NMOS transistors to form the diodes.

In the embodiment configured in this manner, since the transistors D3 and D4 function as diodes, the present embodiment is operationally similar to the first embodiment. That is, the barrier circuit 52 can transmit a change in the input signal IN to the non-inverting node 43 and the inverting node 44 at high speed, and distortion of an output waveform can be prevented.

Further, the voltage drop at the transistors D3 and D4 makes it possible to suppress the level of a voltage applied to the respective terminals of the transistors T35 and T36 and the transistors T37 and T38, and thus a tolerant function is obtained. Note that, since the source, gate and drain are commonly connected in the transistors D3 and D4, it is not necessary to take the withstand voltage into consideration.

Thus, similar effects as those in the first embodiment can be obtained in the present embodiment also.

### Third Embodiment

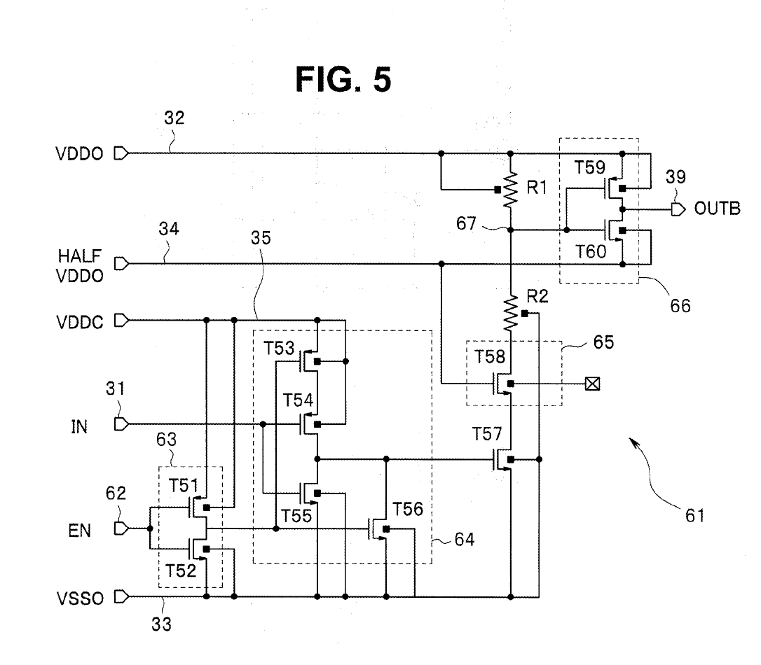

FIG. 5 is a circuit diagram illustrating a third embodiment of the present invention. Components in FIG. 5 that are the same as in FIG. 1 are denoted by the same reference numbers and a description of such components is omitted hereunder.

In a level shift circuit 61 shown in FIG. 5, an enable signal EN is inputted to a terminal 62. A source-drain path of a PMOS transistor T51 and a drain-source path of an NMOS transistor T52 are connected in series between the power supply line 35 and the power supply line 33, and the enable signal EN is applied from the terminal 62 to the gates of the transistors T51 and T52. An inverter 63 is constituted by the transistors T51 and T52. The inverter 63 inverts the enable signal EN, and outputs the inverted signal to an input circuit 64.

The input signal IN is inputted through the input terminal 31 to the input circuit 64. A source-drain path of a PMOS transistor T53, a source-drain path of a PMOS transistor T54, and a drain-source path of an NMOS transistor T55 are serially connected between the power supply line 35 and the power supply line 33. The input signal IN is applied from the input terminal 31 to the gates of the transistors T54 and T55. A drain-source path of an NMOS transistor T56 is connected between the drains of the transistors T54 and T55 and the power supply line 33. The inverted signal of the enable signal EN is inputted from the inverter 63 to the gates of the transistors T53 and T56.

The input circuit 64 constitutes a NOR circuit. If the enable signal EN is at H level, the input circuit 64 functions as an inverter that inverts the input signal IN, while if the enable signal EN is at L level, the input circuit 64 outputs an output at L level, irrespective of the input signal IN. The drain output of the transistors T54 and 155 is supplied to the gate of the NMOS transistor T57 as an output of the input circuit 64.

A non-inverted signal appearing at a non-inverting node 67 that is described later is applied to an output circuit 66 constituting an output portion. A source-drain path of a PMOS transistor T59 and a drain-source path of an NMOS transistor T60 are serially connected between the power supply line 32 and the power supply line 34. A non-inverted signal from the non-inverting node 67 is applied to the gates of the transistors T59 and T60. The transistors T59 and T60 function as an inverter, and invert a non-inverted signal that was inputted thereto, and output the inverted signal to the output terminal 39 as an inverted output OUTB.

Resistances R1 and R2, a drain-source path of an NMOS transistor T58, and a drain-source path of an NMOS transistor T57 are serially connected between the power supply line 32 and the power supply line 33. The gate of the transistor T58 is connected to the power supply line 34, and a barrier circuit 65 is constituted by the transistor T58. Note that a well formed by the resistance R1 is connected to the power supply line 32, and a well formed by the resistance R2 is connected to the power supply line 33.

By setting the resistance ratio between the resistances R1 and R2 to 1:1, when a current flows through the resistances R1 and R2, the potential at the non-inverting node 67 that is a junction point between the resistances R1 and R2 becomes a value in the vicinity of HALFVDDO. Further, when a current does not flow through the resistances R1 and R2, the potential at the non-inverting node 67 is VDDO. When the potential at the non-inverting node 67 is HALFVDDO, the transistor T59 turns “on” and the voltage VDDO that is at H level is obtained as the inverted output OUTB at the output terminal 39. Further, when the potential at the non-inverting node 67 is VDDO, the transistor T60 turns “on” and the voltage HALFVDDO that is at L level is obtained as the inverted output OUTB at the output terminal 39.

Feeding of a current through the resistances R1 and R2 is controlled by the transistor T57. The transistor T57 turns “on” when the input signal IN is at L level, and a current is fed through the resistances R1 and R2. Further, when the input signal IN is at H level, the transistor T57 turns “off” and a current is not fed through the resistances R1 and R2.

In the present embodiment that is configured in this manner, a signal is transmitted to the output circuit 66 depending on whether a current is fed or is not fed through the resistances R1 and R2 in accordance with the input signal IN. Because the resistances R1 and R2 are used for transmitting a signal, only the withstand voltage of the transistor T57 needs to be taken into consideration with regard to the configuration of the barrier circuit 65. The barrier circuit 37 illustrated in FIG. 3 that is a circuit of the related art must necessarily be constructed using MOS transistors at two stages in order to protect transistors connected to the power supply line 32 side and transistors connected to the power supply line 33 side. In contrast, the barrier circuit 65 according to the present embodiment can be constructed using only the single-stage transistor T58. Accordingly, at the time of a transition of a non-inverting node, it is sufficient to drive the single-stage transistor of the barrier circuit 65, and thus operations at a higher speed than in the related art shown in FIG. 3 are possible.

Note that the back gates of the respective PMOS transistors T51, T53 and T54 are connected to the power supply line 35, the back gate of the PMOS transistor T59 is connected to the power supply line 32, the back gates of the respective NMOS transistors T52 and T55 to T57 are connected to the power supply line 33, and the back gate of the NMOS transistor T60 is connected to the power supply line 34. Note that the connecting locations of the back gates shown in FIG. 5 are the connecting locations in an ideal case, and the connecting locations are not limited to the example illustrated in FIG. 5.

Next, operations in the embodiment configured as described above will be described.

In the case of stopping the operation of the level shift circuit 61, the enable signal EN is at L level. In this case, the output of the inverter 63 is at H level, the transistor T53 of the input circuit 64 turns “off” and the transistor T56 of the input circuit 64 turns “on”, and irrespective of the input signal IN, an L-level signal is applied to the gate of the transistor T57. Thereupon, the transistor T57 turns “off” and a current does not flow through the resistances R1 and R2, and the potential at the non-inverting node 67 is continuously VDDO (H level). The transistor T60 is “on”, and the output terminal 39 outputs the inverted output OUTB at L level (HALFVDDO) irrespective of the input signal IN.

When the enable signal EN is at H level, the output of the inverter 63 becomes L level, the transistor T53 of the input circuit 64 turns “on” and the transistor T56 turns “off”. In this case, the input circuit 64 functions as an inverter that inverts the input signal IN, and the inverted signal of the input signal IN is supplied to the gate of the transistor T57.

For example, in a case where the input signal IN is at H level, the transistor T57 turns “off”. In this case, a current does not flow through the resistances R1 and R2, and the potential at the non-inverting node 67 is VDDO (H level). Since the potential at the non-inverting node 67 is VDDO, the transistor T59 turns “off”, the transistor T60 turns “on”, and the inverted output OUTB at L level (HALFVDDO) appears at the output terminal 39.

Conversely, in a case where the input signal IN is at L level, the transistor T57 turns “on”. As a result, the transistor T58 also turns “on”, and a current from the power supply line 32 flows to the power supply line 33 through the resistances R1 and R2 and the transistors T58 and T57. Hence, a voltage drop occurs at the resistances R1 and R2, and the non-inverting node 67 transitions to HALFVDDO.

In the present embodiment, only the resistance R2 and the drain-source path of the transistor T58 are connected between the non-inverting node 67 and the drain of the transistor T57, and a transition of the non-inverting node 67 is performed at a comparatively high speed. Accordingly, a change in the input signal IN appears at the non-inverting node 67 and is transmitted to the output circuit 66 in a sufficiently short time period.

When the potential at the non-inverting node 67 becomes HALFVDDO, the transistor 159 turns “on”, the transistor 160 turns “off”, and the inverted output OUTB that is at H level (VDDO) appears at the output terminal 39. Thus, a change in the input signal IN reliably appears as a change in an output waveform, and the output waveform is not distorted.

### (Tolerant Design)

The voltage VSSO or VDDC is supplied through the power supply lines 35 and 33 to the transistors T51 to T56 constituting the inverter 63 and the input circuit 64, and it is sufficient if these transistors T51 to T56 have a withstand voltage greater than or equal to VDDC. Further, the voltage VDDO or HALFVDDO is supplied through the power supply lines 32 and 34 to the transistors T59 and T60 constituting the output circuit 66, and it is sufficient if these transistors T59 and T60 have a withstand voltage greater than or equal to HALFVDDO. Accordingly, with respect to the transistors T51 to T56 and T59 and T60, a transistor having a withstand voltage greater than or equal to HALFVDDO can be utilized for these transistors, for example, a medium film transistor having a withstand voltage of 1.98 V.

On the other hand, with respect to the transistors T57 and T58, it is necessary to adopt a tolerant structure in a case where these transistors are connected between the power supply line 32 and the power supply line 33 and a medium film transistor is utilized for these transistors. In the present embodiment, a tolerant structure is obtained by means of the barrier circuit 65.

The voltage HALFVDDO is applied to the gate of the transistor T58 constituting the barrier circuit 65. Accordingly, the largest voltage applied to the drain of the transistor T57 is the sum of (HALFVDDO+threshold voltage of transistor T58), and thus the transistor T57 can be constituted by a medium film transistor.

Thus, in the present embodiment, a barrier circuit that is the cause of a decrease in speed can be constituted by a single-stage MOS transistor, and a change in the input signal can be transmitted to the output circuit at high speed while maintaining a tolerant function. Hence, it is possible to prevent a distortion in an output waveform and perform reliable level shifting irrespective of conditions such as the performance of the transistors, the power supply voltages and the temperature.

### Fourth Embodiment

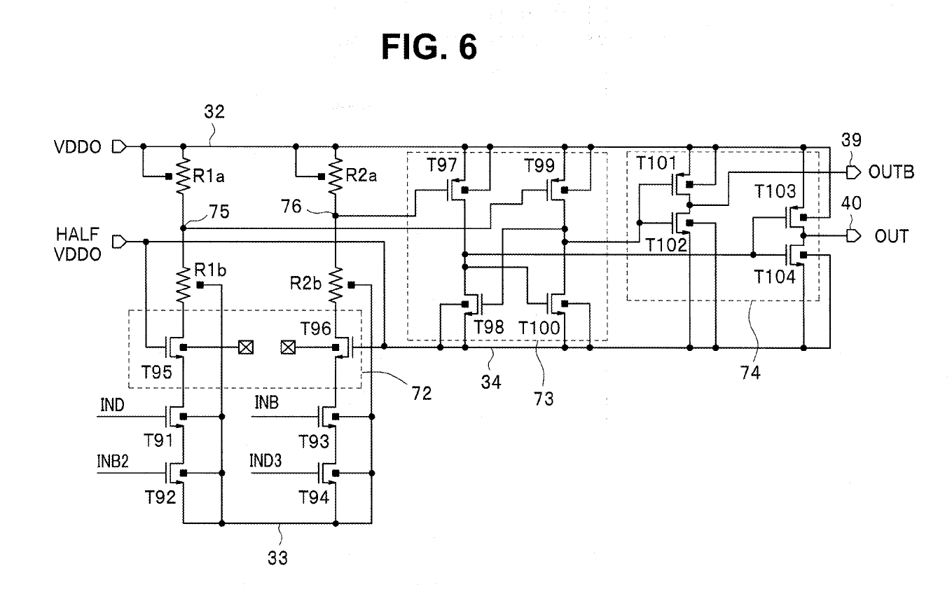

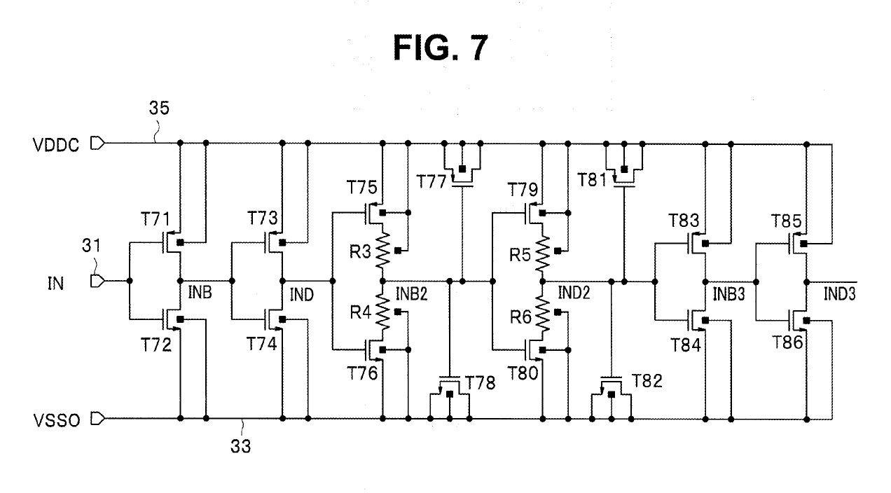

FIG. 6 and FIG. 7 are circuit diagrams illustrating a fourth embodiment of the present invention. Components in FIG. 6 and FIG. 7 that are the same as in FIG. 5 are denoted by the same reference numbers and a description of such components is omitted hereunder.

In the third embodiment, when the input signal IN is at L level, a current is steadily fed through the resistances R1 and R2, and hence there is a concern that the power consumption will increase. Therefore, in the present embodiment a configuration is adopted so as to reduce the power consumption by only feeding a current through the resistances during a comparatively short period (hereunder, referred to as “transition period”) immediately after the input signal IN changes from H level to L level or from L level to H level.

FIG. 7 illustrates a circuit that constitutes an input circuit into which the input signal IN is inputted, and that also generates a timing signal for generating a pulse signal corresponding to a transition period based on the input signal IN. Although FIG. 7 illustrates an example that uses a six-stage inverter circuit, various circuits that generate a similar timing signal based on the input signal IN can be adopted.

A source-drain path of a PMOS transistor T71 and a drain-source path of an NMOS transistor T72 are connected in series between the power supply line 35 and the power supply line 33 in FIG. 7, and the input signal IN is supplied to the gates of the transistor T71 and T72 through the input terminal 31. The transistors T71 and T72 constitute a first-stage inverter, and invert the input signal IN and output an inverted signal INB.

A source-drain path of a PMOS transistor T73 and a drain-source path of an NMOS transistor T74 constituting a second-stage inverter are connected in series between the power supply line 35 and the power supply line 33. The inverted signal INB is supplied to the gates of the transistor T73 and T74. The second-stage inverter formed by the transistor T73 and T74 inverts the inverted signal INB and outputs a non-inverted signal IND.

A source-drain path of a PMOS transistor T75, resistances R3 and R4, and a drain-source path of an NMOS transistor T76 constituting an inverter at a third stage are connected in series between the power supply line 35 and the power supply line 33. The non-inverted signal IND is supplied to the gates of the transistors T75 and T76. The third-stage inverter formed by the transistors T75 and T76 inverts the non-inverted signal IND and outputs an inverted signal INB2.

A junction point between the resistances R3 and R4 is connected to the gate of a PMOS transistor T77 and the gate of an NMOS transistor T78. The drain and source of the transistor T77 are connected to the power supply line 35. The drain and source of the transistor T78 are connected to the power supply line 33. Each of the transistors T77 and T78 acts as a capacitance. Performance of inversion from the non-inverted signal IND to the inverted signal INB2 is delayed by a delay time in accordance with a time constant circuit constituted by the resistances R3 and R4 and the transistors T77 and T78. That is, a delay inverter is constituted by the transistors T75 to T78 and the resistances R3 and R4.

Transistors T79 to T82 and resistances R5 and R6 are configured in the same manner as the transistors T75 to T78 and the resistances R3 and R4, and constitute a delay inverter that is at a fourth stage. The fourth-stage delay inverter delays and inverts the inverted signal INB2 that was inputted thereto, and outputs a non-inverted signal IND2.

A source-drain path of a PMOS transistor T83 and a drain-source path of an NMOS transistor T84 constituting an inverter at a fifth stage are connected in series between the power supply line 35 and the power supply line 33. The transistors T83 and T84 invert the non-inverted signal IND2 that was inputted to the respective gates thereof, and output an inverted signal INB3.

Further, a source-drain path of a PMOS transistor T85 and a drain-source path of an NMOS transistor T86 constituting an inverter at a sixth stage are connected in series between the power supply line 35 and the power supply line 33. The transistors T85 and T86 invert the inverted signal INB3 that was inputted to the respective gates thereof, and output a non-inverted signal IND3.

Note that the back gates of the respective PMOS transistors T71, T73, T75, T77, T79, T81, T83 and T85 are connected to the power supply line 35, and the back gates of the respective NMOS transistors T72, T74, T76, T78, T80, T82, T84 and T86 are connected to the power supply line 35. Note that the connecting locations of the back gates shown in FIG. 7 are the connecting locations in an ideal case, and the connecting locations are not limited to the example illustrated in FIG. 7.

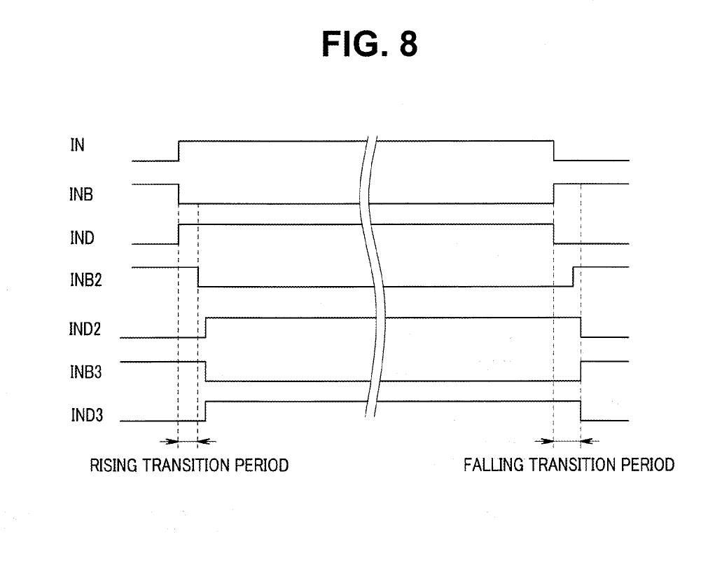

By appropriately setting a delay time of the respective inverters shown in FIG. 7, for example, as shown in FIG. 8, the non-inverted signal IND that rises with almost no delay from the rising edge of the input signal IN, and the inverted signal INB2 that falls after a predetermined period (hereunder, referred to as “rising transition period”) from the rising edge of the non-inverted signal IND can be generated. Further, the inverted signal INB that rises with almost no delay from the falling edge of the input signal IN, and the non-inverted signal IND3 that falls after a predetermined period (hereunder, referred to as “falling transition period”) from the rising edge of the inverted signal INB can be generated.

In the example in FIG. 5, a circuit portion that is arranged between the power supply line 32 and the power supply line 33 and that transmits the input signal IN to the output circuit is constituted by only a single-system signal path that passes through the non-inverting node 67. Although the non-inverting node 67 is configured to maintain a level in accordance with the input signal IN, in the present embodiment, in order to enable temporary feeding of a current in a signal path, two paths are provided, namely, a signal path in which a current is fed only in a predetermined period (rising transition period) from the rising edge of the input signal IN, and a signal path in which a current is fed only in a predetermined period (falling transition period) from the falling edge of the input signal IN. Note that the inverters shown in FIG. 7 are set so that the rising and falling transition periods become sufficiently long time periods for turning the transistors T91 to T94 “on”.

In FIG. 6, one signal path is constituted by resistances R1a and R1b, a drain-source path of an NMOS transistor T95, a drain-source path of an NMOS transistor T91 and a drain-source path of an NMOS transistor T92 that are serially connected between the power supply line 32 and the power supply line 33. The other signal path is constituted by resistances R2a and R2b, a drain-source path of an NMOS transistor T96, a drain-source path of an NMOS transistor T93 and a drain-source path of an NMOS transistor T94 that are serially connected between the power supply line 32 and the power supply line 33. The circuit shown in FIG. 6 is configured so that the non-inverted signal IND, the inverted signal INB2, the inverted signal INB or the non-inverted signal IND3 that are the respective outputs of the inverters at the second, third, first and sixth stages in FIG. 7 are applied to the gates of the transistors T91 to T94 in FIG. 6, respectively.

The transistor T95 and T96 are configured so that the voltage HALFVDDO is supplied to the respective gates thereof, and a barrier circuit 72 is constituted by the single-stage transistors T95 and T96.

The transistors T91 and T92 both turn “on” only during a predetermined period (rising transition period) from the rising edge of the input signal IN. During other periods, at least one of the transistors 191 and 192 is “off”. When both of the transistors T91 and T92 turn “on”, a current can be fed through the resistances R1a and Rib, and during the rising transition period the potential at a non-inverting node 75 that is a junction point between the resistances R1a and R1b can be set to HALFVDDO. Note that, during a period other than the rising transition period, the potential at the non-inverting node 75 is VDDO.

Similarly, the transistors T93 and T94 both turn “on” only during a predetermined period (falling transition period) from the falling edge of the input signal IN. During other periods, at least one of the transistors T93 and T94 is “off”. When both of the transistors T93 and T94 turn “on”, a current can be fed through the resistances R2a and R2b, and during the falling transition period the potential at an inverting node 76 that is a junction point between the resistances R2a and R2b can be set to HALFVDDO. Note that, during a period other than the falling transition period, the potential at the inverting node 76 is VDDO.

The non-inverting node 75 and the inverting node 76 are connected to the gates of PMOS transistors T99 and T97, respectively. A source-drain path of the transistor T97 and a drain-source path of an NMOS transistor T98 are serially connected between the power supply line 32 and the power supply line 34. A source-drain path of the transistor T99 and a drain-source path of an NMOS transistor T100 are serially connected between the power supply line 32 and the power supply line 34. The gate of the transistor T98 is connected to the drain of the transistor T99, and the gate of the transistor T100 is connected to the drain of the transistor T97, and thus a latch circuit 73 is constituted by the transistors T97 to T100.

In the rising transition period, the potential at the non-inverting node 75 is HALFVDDO and the potential at the inverting node 76 is VDDO. In this case, the transistor T97 is “off” and the transistor T99 turns “on”. When the transistor T99 turns “on”, the drain of the transistor T99 becomes H level, the transistor T98 turns “on”, and the drain of the transistor T97 becomes L level. As a result, the transistor T100 turns “off”, and the drain of the transistor T99 is maintained at H level.

In the falling transition period, the potential at the non-inverting node 75 is VDDO and the potential at the inverting node 76 is HALFVDDO. In this case, the transistor T99 is “off” and the transistor T97 turns “on”. When the transistor T97 turns “on”, the drain of the transistor T97 becomes H level, the transistor T100 turns “on”, and the drain of the transistor T99 becomes L level. As a result, the transistor T98 turns “off”, and the drain of the transistor T97 is maintained at H level.

During a period other than the rising transition period and the falling transition period the potential at both the non-inverting node 75 and the inverting node 76 is VDDO. In this case, the transistor T97 and T99 are both “off”. If one of the transistors T98 and T100 is “on”, the other is “off”, and the drains of the transistors T97 and T99 are maintained at the potential thereof in the immediately preceding rising transition period or falling transition period.

A source-drain path of a PMOS transistor T101 and a drain-source path of an NMOS transistor T102 are serially connected between the power supply line 32 and the power supply line 34. A source-drain path of a PMOS transistor T103 and a drain-source path of an NMOS transistor T104 are serially connected between the power supply line 32 and the power supply line 34. The drain of the transistor T99 is connected to the gates of the transistors T101 and T102. The drain of the transistor T97 is connected to the gates of the transistors T103 and T104. An output circuit 74 is constituted by the transistors T101 to 104. An output portion is constituted by the latch circuit 73 and output circuit 74. The drains of the transistors T101 and T102 are connected to the output terminal 39 for the inverted output OUTB, and the drains of the transistors T103 and T104 are connected to the output terminal 40 for the non-inverted output OUT.

Note that the back gates of the respective NMOS transistors T91 to T94 are connected to the power supply line 33, the back gates of the respective NMOS transistors T95, T96, T98, T100, T102 and T104 are connected to the power supply line 34, and the back gates of the respective PMOS transistors T97, T99, T101 and 1103 are connected to the power supply line 32. Note that the connecting locations of the back gates that are shown in FIG. 6 are the connecting locations in an ideal case, and the connecting locations are not limited to the example illustrated in FIG. 6.

Next, operations in the embodiment configured as described above will be described.

The input signal IN is supplied to the gates of the transistors T71 and T72 through the input terminal 31 shown in FIG. 7. The input signal IN is sequentially inverted by the inverters at the first to sixth stages in FIG. 7, and the non-inverted signal IND that rises with almost no delay from the rising edge of the input signal IN, and the inverted signal INB2 that falls after the rising transition period from the rising edge of the non-inverted signal IND, as well as the inverted signal INB that rises with almost no delay from falling edge of the input signal IN, and the non-inverted signal IND3 that falls after the falling transition period from the rising edge of the inverted signal INB are obtained.

The aforementioned non-inverted signal IND, inverted signal INB2, inverted signal INB and non-inverted signal IND3 are supplied to the gates of the transistors T91 to 94 shown in FIG. 6, respectively. When the input signal IN rises from L level to H level, the transistors T91 and T92 turn “on” during only the rising transition period, and the potential at the non-inverting node 75 is changed to HALFVDDO. As a result, the drain of the transistor T99 of the latch circuit 73 becomes H level and the drain of the transistor T97 becomes L level, and the transistors T102 and T103 of the output circuit 74 turn “on”. Thus, the inverted output OUTB at L level is outputted to the output terminal 39, and the non-inverted output OUT at H level is outputted to the output terminal 40.

Note that when the rising transition period ends, at least one of the transistors T91 and T92 turns “off”, a current no longer flows through the resistances R1a and R1b, and thus the power consumption is reduced. Further, even if the non-inverting node 75 changes to L level, the H level of the drain of the transistor T99 and the L level of the drain of the transistor T97 are maintained by the latch circuit 73, and the inverted output OUTB and the non-inverted output OUT do not change.

Next, it is assumed that the input signal IN falls from H level to L level. Thereupon, the transistors T93 and T94 turn “on” during only the falling transition period, and the potential at the inverting node 76 is changed to HALFVDDO. As a result, the drain of the transistor T97 of the latch circuit 73 becomes H level and the drain of the transistor T99 becomes L level, and the transistors T101 and 1104 of the output circuit 74 turn “on”. Thus, the inverted output OUTB at H level is outputted to the output terminal 39, and the non-inverted output OUT at L level is outputted to the output terminal 40.

Note that, when the falling transition period ends, at least one of the transistors T93 and T94 turns “off”, a current no longer flows through the resistances R2a and R2b, and thus the power consumption is reduced. Further, even if the inverting node 76 changes to L level, the H level of the drain of the transistor T97 and the L level of the drain of the transistor T99 are maintained by the latch circuit 73, and the inverted output OUTB and the non-inverted output OUT do not change.

In the present embodiment also, only the drain-source path of the single-stage transistor T95 is connected between the non-inverting node 75 and the drain of the transistor T91, and only the drain-source path of the single-stage transistor T96 is connected between the inverting node 76 and the drain of the transistor T93, and thus transitions of the non-inverting node 75 and the inverting node 76 are performed at a comparatively high speed. Accordingly, a change in the input signal IN appears at the non-inverting node 75 and the inverting node 76 in a sufficiently short time period, and is transmitted to the output circuit 74. Thus, a change in the input signal IN reliably appears as a change in an output waveform, and the output waveform is not distorted.

### (Tolerant Design)

The voltage VSSO or VDDC is supplied through the power supply lines 35 and 33 to the respective transistors T71 to T86 shown in FIG. 7, and it is sufficient if these transistor T71 to T86 have a withstand voltage greater than or equal to VDDC. Further, the voltage VDDO or HALFVDDO is supplied through the power supply lines 32 and 34 to the respective transistors T97 to T104 shown in FIG. 6, and it is sufficient if these transistors T97 to T104 have a withstand voltage greater than or equal to HALFVDDO. Accordingly, with respect to the transistors T71 to T86 and T97 to T104, a transistor having a withstand voltage greater than or equal to HALFVDDO, for example, a medium film transistor having a withstand voltage of 1.98 V, can be utilized for these transistors.

On the other hand, with respect to the transistors T91 to T94, it is necessary to adopt a tolerant structure in a case where these transistors are connected between the power supply line 32 and the power supply line 33 and a medium film transistor is utilized for these transistors. In the present embodiment, a tolerant structure is obtained by means of the barrier circuit 72.

The voltage HALFVDDO is applied to the gates of the transistors T95 and T96 constituting the barrier circuit 72. Accordingly, the largest voltage applied to the drains of the transistors T91 and T93 is the sum of (HALFVDDO+threshold voltage of transistors T95 and T96), and thus the transistors T91 to T94 can be constituted by a medium film transistor.

Thus, in the present embodiment also, a barrier circuit that is the cause of a decrease in speed can be constituted by a single-stage MOS transistor, and a change in the input signal can be transmitted to the output circuit at high speed while maintaining a tolerant function. Further, in the present embodiment, a configuration is adopted so that a current flows through the resistances only during a comparatively short time period when the input signal changes, and thus an increase in power consumption can be prevented.

### Fifth Embodiment

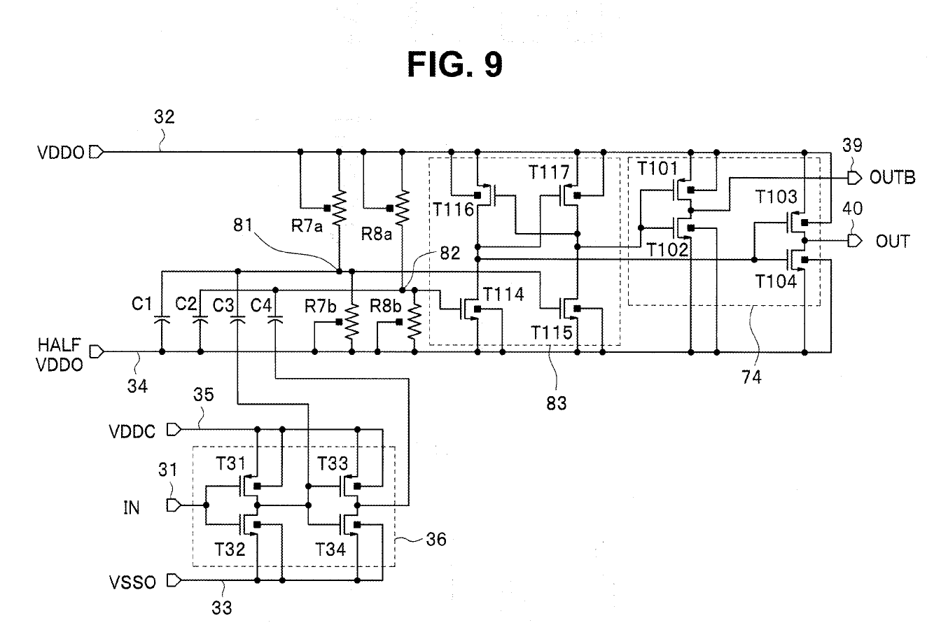

FIG. 9 is a circuit diagram illustrating a fifth embodiment of the present invention. Components in FIG. 9 that are the same as in FIG. 1, FIG. 6 and FIG. 7 are denoted by the same reference numbers and a description of such components is omitted hereunder.

A latch circuit 83 has a similar configuration to the latch circuit 73 in FIG. 6. A source-drain path of a PMOS transistor T116 and a drain-source path of an NMOS transistor T114 are serially connected between the power supply line 32 and the power supply line 34, and a non-inverting node 82 is connected to the gate of the transistor T114. Further, a source-drain path of a PMOS transistor T117 and a drain-source path of an NMOS transistor T115 are serially connected between the power supply line 32 and the power supply line 34, and an inverting node 81 is connected to a gate of the transistor 7115. The drain of the transistor TI 14 is connected to the gate of the transistor T117. The drain of the transistor T115 is connected to the gate of the transistor T116.

Resistances R7a and R7b are serially connected between the power supply line 32 and the power supply line 34. A junction point between the resistances R7a and R7b serves as the inverting node 81. Further, resistances R8a and R8b are serially connected between the power supply line 32 and the power supply line 34. A junction point between the resistances R8a and R8b serves as the non-inverting node 82. By setting the resistance values of the resistances R7a and R7h to appropriate values, the inverting node 81 can be set at an intermediate potential between VDDO and HALFVDDO in a steady state (hereunder, referred to as “steady-state potential”). Further, by setting the resistance values of the resistances R8a and R8b to appropriate values, the non-inverting node 82 can be set at a steady-state potential that is midway between VDDO and HALFVDDO in a steady state.

In the present embodiment, the inverting node 81 is connected to the power supply line 34 through a capacitor C1, and is connected to the drains of the transistors T31 and T32 through a capacitor C3. Further, the non-inverting node 82 is connected to the power supply line 34 through a capacitor C2, and is connected to the drains of the transistors T33 and T34 through a capacitor C4.

In the present embodiment, by appropriately setting the capacities of the capacitors C1 and C3 and the resistance values of the resistances R7a and R7b, the inverting node 81 is raised to a value in the vicinity of VDDO immediately after a signal (inverted signal of the input signal IN) appearing in the drains of the transistors T31 and T32 changes from L level to H level, and the inverting node 81 is lowered to a value in the vicinity of HALFVDDO immediately after the signal (inverted signal of the input signal IN) appearing in the drains of the transistors T31 and T32 changes from H level to L level. Note that, by appropriately setting the capacities of the capacitors C1 and C3 and the resistance values of the resistances R7a and R7b, the level of the inverting node 81 returns to the steady-state potential after a predetermined period elapses from the rising edge or falling edge of the inverted signal of the input signal IN that appears in the drains of the transistors T31 and T32.

Similarly, by appropriately setting the capacities of the capacitors C2 and C4 and the resistance values of the resistances R8a and R8b, the non-inverting node 82 is raised to a value in the vicinity of VDDO immediately after a non-inverted signal appearing in the drains of the transistors T33 and T34 changes from L level to H level, and the non-inverting node 82 is lowered to a value in the vicinity of HALFVDDO immediately after the non-inverted signal appearing in the drains of the transistors T33 and T34 changes from H level to L level. Note that, by appropriately setting the capacities of the capacitors C2 and C4 and the resistance values of the resistances R8a and R8b, the level of the non-inverting node 82 returns to the steady-state potential after a predetermined period elapses from the rising edge or falling edge of the non-inverted signal appearing in the drains of the transistor T33 and T34.

Note that the back gates of the NMOS transistors T114 and T115 are connected to the power supply line 34, and the back gate of the PMOS transistors T116 and T117 are connected to the power supply line 32.

Next, operations in the embodiment configured as described above will be described.

The input signal IN is supplied to the gates of the transistors T31 and T32 through the input terminal 31. It is assumed that at this time the input signal IN changes from L level to H level. Thereupon, the drains of the transistors T31 and T32 change from H level to L level. This change is transmitted to the inverting node 81 by the capacitors C1 and C3, and the level of the inverting node 81 changes for a predetermined time period only from the steady-state potential to HALF VDDO as the L level. Further, in this case, the drains of the transistors T33 and T34 change from L level to H level, this change is transmitted to the non-inverting node 82 by the capacitors C2 and C4, and the level of the non-inverting node 82 changes for a predetermined time period only from the steady-state potential to VDDO as the H level.

When the non-inverting node 82 becomes H level, the transistor T114 turns “on” and the drain of the transistor T114 becomes L level. Thereupon, the transistor T117 turns “on”, and the drain of the transistor T117 becomes H level. As a result, the transistors T102 and T103 of the output circuit 74 turn “on”. Thus, the inverted output OUTB at L level is outputted to the output terminal 39, and the non-inverted output OUT at H level is outputted to the output terminal 40.

Note that the inverting node 81 and the non-inverting node 82 return to the steady-state potential after a predetermined period elapses from the rising edge of the input signal IN. The H level of the drain of the transistor T117 and the L level of the drain of the transistor T116 of the latch circuit 83 are maintained, and the inverted output OUTB and the non-inverted output OUT do not change.

Next, it is assumed that the input signal IN falls from H level to L level. Thereupon, the drains of the transistors T31 and T32 change from L level to H level. This change is transmitted to the inverting node 81 by the capacitors C1 and C3, and the level of the inverting node 81 changes for a predetermined time period only from the steady-state potential to VDDO as the H level. Further, in this case, the drains of the transistors T33 and T34 change from H level to L level, this change is transmitted to the non-inverting node 82 by the capacitors C2 and C4, and the level of the non-inverting node 82 changes for a predetermined time period only from the steady-state potential to HALFVDDO as the L level.

When the inverting node 81 becomes H level, the transistor T115 turns “on” and the drain of the transistor T115 becomes L level. Thereupon, the transistor T116 turns “on”, and the drain of the transistor T116 becomes H level. As a result, the transistors T101 and T104 of the output circuit 74 turn “on”. Thus, the inverted output OUTB at H level is outputted to the output terminal 39, and the non-inverted output OUT at L level is outputted to the output terminal 40.

In the present embodiment, a change in the input signal IN is instantaneously transmitted to the inverting node 81 by means of the capacitors C1 and C3, and is instantaneously transmitted to the non-inverting node 82 by means of the capacitors C2 and C4. Accordingly, a change in the input signal IN is transmitted to the output circuit 74 in a sufficiently short time period. Thus, a change in the input signal IN reliably appears as a change in an output waveform, and the output waveform is not distorted.

Further, in the present embodiment all the transistors are connected between the power supply line 32 and the power supply line 34 or between the power supply line 35 and the power supply line 33, and are not connected between the power supply line 32 and the power supply line 33. Accordingly, all the transistors can be constituted by, for example, a medium film transistor having a withstand voltage of 1.98 V.

Thus, similar effects as in the respective embodiments described above can be obtained in the present embodiment also.

Note that although examples of outputting both of an inverted output and a non-inverted output are illustrated in FIG. 1, FIG. 4, FIG. 6 and FIG. 9, a configuration may also be adopted in which only one of an inverted output and a non-inverted output is outputted.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A level shift circuit, comprising:
a first power supply line to which a first voltage is supplied;
a second power supply line to which a second voltage that is higher than the first voltage is supplied;
a third power supply line to which a third voltage that is higher than the second voltage is supplied;
a fourth power supply line to which a fourth voltage that is higher than the first voltage and lower than the third voltage is supplied;
an input circuit to which voltages are supplied from the first and second power supply lines, and which is configured to receive an input signal;
first and second signal paths that are connected in parallel between the first power supply line and the third power supply line;
first and second switching elements configured to control conduction of the first and second signal paths, respectively, based on the input signal that the input circuit receives;
first and second diodes provided on the first and second signal paths, respectively, at positions that are on a side of the third power supply line with respect to the first and second switching elements;
a cross-coupled circuit configured to make one of a first node which is located on the first path at a position that is on the side of the third power supply line with respect to the first diode and a second node which is located on the second path at a position that is on the side of the third power supply line with respect to the second diode a high level and make the other of the first node and the second node a low level, and that is provided on the first and second signal paths at a position that is on the side of the third power supply line with respect to the first and second nodes; and
an output circuit to which voltages are supplied from the third and fourth power supply lines, and which is configured to output an output signal based on at least one of a signal appearing at the first node and a signal appearing at the second node.

2. The level shift circuit according to claim 1, wherein:
the input circuit has a non-inverted output terminal configured to output a non-inverted signal based on the input signal, and an inverted output terminal configured to output an inverted signal based on the input signal;
the first switching element is configured so that conduction is controlled by a non-inverted signal appearing at the non-inverted output terminal of the input circuit; and
the second switching element is configured so that conduction is controlled by an inverted signal appearing at the inverted output terminal of the input circuit.

3. The level shift circuit according to claim 1, wherein:
the first diode comprises a first bipolar transistor in which an emitter is connected to the first node, a base is connected to the first switching element, and a collector is connected to the first power supply line;
the second diode comprises a second bipolar transistor in which an emitter is connected to the second node, a base is connected to the second switching element, and a collector is connected to the first power supply line.

4. The level shift circuit according to claim 1, wherein:
the first diode comprises a first MOS transistor in which a gate, a source and a drain are connected to the first node, and a back gate is connected to the first switching element;
the second diode comprises a second MOS transistor in which a gate, a source and a drain are connected to the second node, and a back gate is connected to the second switching element.

5. A level shift circuit, comprising:
a first power supply line to which a first voltage is supplied;
a second power supply line to which a second voltage that is higher than the first voltage is supplied;
a third power supply line to which a third voltage that is higher than the second voltage is supplied;
a fourth power supply line to which a fourth voltage that is higher than the first voltage and lower than the third voltage is supplied;
an input circuit to which voltages are supplied from the first and second power supply lines, and which is configured to receive an input signal;
a first signal path that is connected between the first power supply line and the third power supply line;
a first switching element configured to control conduction of the first signal path based on the input signal that the input circuit receives;
first and second resistance elements provided in series on the first signal path;
a first MOS transistor in which a drain-source path is provided on the first signal path between the first and second resistance elements and the first switching element, and in which a voltage is supplied to a gate from the fourth power supply line; and
an output portion to which voltages are supplied from the third and fourth power supply lines, and which is configured to output an output signal based on a signal appearing at a first node on the first signal path between the first resistance element and the second resistance element.

6. The level shift circuit according to claim 5, further comprising:
an enable circuit to which voltages are supplied from the first and second power supply lines, and which is configured to allow reception of the input signal by the input circuit.

7. The level shift circuit according to claim 5, further comprising:
a second signal path connected in parallel to the first signal path between the first power supply line and the third power supply line;
a second switching element configured to cause the second signal path to conduct based on the input signal that the input circuit receives;
third and fourth resistance elements provided in series on the second signal path; and
a second MOS transistor in which a drain-source path is provided on the second signal path between the third and fourth resistance elements and the second switching element, and in which a voltage is supplied to a gate from the fourth power supply line;
wherein the output portion comprises:
a latch circuit to which voltages are supplied from the third and fourth power supply lines, and which is configured to latch at least one of a signal appearing at a first node on the first signal path between the first resistance element and the second resistance element and a signal appearing at a second node on the second signal path between the third resistance element and the fourth resistance element; and
an output circuit to which voltages are supplied from the third and fourth power supply lines, and which is configured to output an output signal based on the signal that the latch circuit latches.

8. The level shift circuit according to claim 7, wherein:
the input circuit comprises a timing signal generation circuit configured to, based on the input signal, generate a signal for causing the first signal path to conduct for only a first transition period and a signal for causing the second signal path to conduct for only a second transition period and drive the first and second switching elements.

9. The level shift circuit according to claim 8, wherein:
the timing signal generation circuit comprises inverters at a plurality of stages to which voltages are supplied from the first and second power supply lines, with the input signal being inputted to a first-stage inverter.

10. The level shift circuit according to claim 9, wherein:
the timing signal generation circuit comprises the inverters that are connected in a cascade arrangement in six stages.

11. The level shift circuit according to claim 7, wherein:
the first switching element comprises a first MOS transistor having a gate into which a non-inverted signal that is based on the input signal is inputted, and a second MOS transistor having a gate into which an inverted signal that is based on the input signal is inputted, with respective drain-source paths of the first MOS transistor and the second MOS transistor being serially connected on the first signal path;
the second switching element comprises a third MOS transistor having a gate into which an inverted signal that is based on the input signal is inputted, and a fourth MOS transistor having a gate into which a non-inverted signal that is based on the input signal is inputted, with respective drain-source paths of the third MOS transistor and the fourth MOS transistor being serially connected on the second signal path.

12. The level shift circuit according to claim 11, wherein:
the non-inverted signal that is inputted to the gate of the first MOS transistor rises when the first transition period starts and the inverted signal that is inputted to the gate of the second MOS transistor falls when the first transition period ends, or the non-inverted signal that is inputted to the gate of the first MOS transistor falls when the first transition period starts and the inverted signal that is inputted to the gate of the second MOS transistor rises when the first transition period ends; and
the inverted signal that is inputted to the gate of the third MOS transistor rises when the second transition period starts and the non-inverted signal that is inputted to the gate of the fourth MOS transistor falls when the second transition period ends, or the inverted signal that is inputted to the gate of the third MOS transistor falls when the second transition period starts and the non-inverted signal that is inputted to the gate of the fourth MOS transistor rises when the second transition period ends.

13. The level shift circuit according to claim 11, wherein:
the timing signal generation circuit comprises inverters that are connected in a cascade arrangement in six stages to which voltages are supplied from the first and second power supply lines, with the input signal being inputted to a first-stage inverter, the inverters including a second-stage inverter configured to invert and output an output of the first-stage inverter, third-stage and fourth-stage inverters comprising a delay circuit configured to delay an output of the second-stage inverter, a fifth-stage inverter configured to invert and output an output of the fourth-stage inverter, and a sixth-stage inverter configured to invert and output an output of the fifth-stage inverter; and
the output of the second-stage inverter is inputted to the gate of the first MOS transistor, the output of the third-stage inverter is inputted to the gate of the second MOS transistor, the output of the first-stage inverter is inputted to the gate of the third MOS transistor, and the output of the sixth-stage inverter is inputted to the gate of the fourth MOS transistor.

14. The level shift circuit according to claim 13, wherein the delay circuit comprises:
a first delay inverter that includes: a source-drain path of a fifth MOS transistor, fifth and sixth resistance elements, and a drain-source path of a sixth MOS transistor that are serially connected between the second power supply line and the first power supply line; a seventh MOS transistor having a drain and a source that are connected to the second power supply line; and an eighth MOS transistor having a drain and a source that are connected to the first power supply line; and that is configured so that an output of the second-stage inverter is inputted to gates of the fifth and sixth MOS transistors, and a junction point between the fifth and sixth resistance elements that serves as an output terminal is connected to gates of the seventh and eighth MOS transistors, and
a second delay inverter that includes: a source-drain path of a ninth MOS transistor, seventh and eighth resistance elements, and a drain-source path of a tenth MOS transistor that are serially connected between the second power supply line and the first power supply line; an eleventh MOS transistor having a drain and a source that are connected to the second power supply line; and a twelfth MOS transistor having a drain and a source that are connected to the first power supply line; and that is configured so that an output of the first delay inverter is inputted to gates of the ninth and tenth MOS transistors, and a junction point between the seventh and eighth resistance elements that serves as an output terminal is connected to gates of the eleventh and twelfth MOS transistors.

15. A level shift circuit, comprising:
a first power supply line to which a first voltage is supplied;
a second power supply line to which a second voltage that is higher than the first voltage is supplied;
a third power supply line to which a third voltage that is higher than the second voltage is supplied;
a fourth power supply line to which a fourth voltage that is higher than the first voltage and lower than the third voltage is supplied;
an input circuit to which voltages are supplied from the first and second power supply lines, and which is configured to receive an input signal;
first and second signal paths that are connected in parallel between the third power supply line and the fourth power supply line;
first and second resistance elements that are provided in series on the first signal path;
third and fourth resistance elements that are provided in series on the second signal path;
a first capacitor configured to transmit a change in the input signal that is received by the input circuit to a first node on the first signal path between the first resistance element and the second resistance element;
a second capacitor configured to transmit a change in the input signal that is received by the input circuit to a second node on the second signal path between the third resistance element and the fourth resistance element;
a latch circuit to which voltages are supplied from the third and fourth power supply lines, and which is configured to latch at least one of a signal appearing at the first node and a signal appearing at the second node; and
an output circuit to which voltages are supplied from the third and fourth power supply lines, and which is configured to output an output signal based on a signal that the latch circuit latches.

16. The level shift circuit according to claim 15, wherein:
the input circuit has a non-inverted output terminal configured to output a non-inverted signal based on the input signal, and an inverted output terminal configured to output an inverted signal based on the input signal;
the first capacitor is connected between the non-inverted output terminal of the input circuit and the first node; and
the second capacitor is connected between the inverted output terminal of the input circuit and the second node.
